(19) United States
(12) Patent Application Publication
(10) Pub. No.: US 2018/0255637 A1
(43) Pub. Date: Sep. 6, 2018

(54) PRINTING ELECTRICALLY CONDUCTIVE INK ON FABRIC

(71) Applicant: Microsoft Technology Licensing, LLC, Redmond, WA (US)

(72) Inventors: Siyuan Ma, Bothell, WA (US); James David Holbery, Bellevue, WA (US); Hanbit Jin, Tokyo (JP)

(73) Assignee: Microsoft Technology Licensing, LLC, Redmond, WA (US)

(21) Appl. No.: 15/446,898

(22) Filed: Mar. 1, 2017

(51) Int. Cl. H05K 1/09; B41F 15/00; H05K 1/03; H05K 3/12; C09D 11/52; C09D 11/106; C09D 11/102; C09D 11/033

(52) U.S. Cl. CPC H05K 1/092; B41F 15/00; H05K 1/038; C09D 11/033; C09D 11/52; C09D 11/106; C09D 11/102; H05K 3/1225

(57) ABSTRACT

One disclosed example comprises an ink formulated for printing an electrically conductive trace on a flexible fabric substrate. The ink includes an elastomer and a liquid vehicle capable of swelling the elastomer, the liquid vehicle having a boiling point of 150° C. or greater at one atmosphere. A plurality of non-spherical, electrically conductive particles are suspended in the liquid vehicle to impart electrical conductivity to the ink.

### BACKGROUND

Printing technologies have advanced significantly in recent years. Ink-jet printing, for example, can now be used with various exotic inks and substrates, resulting in functionally patterned surfaces for electronic and optical components. Other conventional printing methods include gravure and slot-die, for example. Some printing techniques may be limited, however, in terms of speed and scalability. Often it is desirable to rapidly pattern large substrates at high manufacturing speed. In this scenario, traditional screen printing technologies may be more attractive.

### SUMMARY

Examples are disclosed that relate to printing electrically conductive ink patterns on flexible, fabric substrates. One example provides an ink formulated for printing an electrically conductive trace on a flexible fabric substrate. The ink includes an elastomer, and a liquid vehicle capable of swelling the elastomer, the liquid vehicle having a boiling point of 150° C. or greater at one atmosphere. A plurality of non-spherical, electrically conductive particles are suspended in the liquid vehicle to impart electrical conductivity to the ink.

This Summary is provided to introduce in a simplified form a selection of concepts that are further described in the Detailed Description below. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 shows an example flexible component of an electronic device.

FIG. 2 shows an example screen printing apparatus and fabric substrate.

FIG. 3 shows an example screen printing screen.

FIG. 4 illustrates an example method to deposit a pattern of electrically conductive ink onto a fabric substrate.

### DETAILED DESCRIPTION

Aspects of this disclosure will now be described by example and with reference to the drawing figures listed above. Components, process steps, and other elements that may be substantially the same in one or more of the figures are identified coordinately and described with minimal repetition. It will be noted, however, that elements identified coordinately may also differ to some degree. It will be further noted that the figures are schematic and generally not drawn to scale. Rather, the various drawing scales, aspect ratios, and numbers of components shown in the figures may be purposely distorted to make certain features or relationships easier to see.

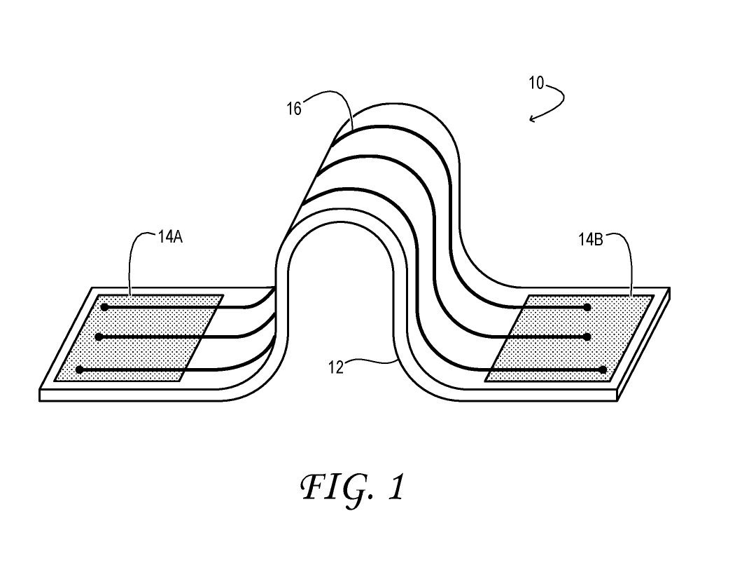

FIG. 1 shows aspects of an example flexible component 10 of an electronic device. The flexible component includes a fabric substrate 12 with electronic circuits 14A and 14B mounted thereon. The fabric substrate comprises an intimate arrangement of threads, which may include cotton, nylon, polyurethane, polysiloxane, and/or polyester, for example. In some examples, the fabric substrate may include spandex and/or tricot, to impart stretchability. In one particular example, the fabric substrate may be FR3600, a product of UTAX Co., Ltd. of Nishiwaki, Japan. This material is a 2-way stretch tricot comprising 76% 30-denier nylon and 24% 30-denier polyurethane. In other examples, any other suitable type of fabric may be used.

Continuing with FIG. 1, an electrically conductive pattern 16 is deposited on fabric substrate 12 to provide one or more electrically conductive pathways, or traces, from one electronic circuit 14 to another. Collected within the threads at each trace of the pattern is a non-volatile residue of an electrically conductive ink. The term ‘electrically conductive ink’ is used herein to indicate that the residue of the ink, after the ink has dried or cured, is a good conductor of electricity, without reference to electrical conductivity prior to drying or curing. As described in further detail below, the electrically conductive ink may comprise an elastomer, a plurality of non-spherical, electrically conductive particles, and a liquid vehicle capable of swelling the elastomer and having a relatively high boiling point in comparison to the solvents typically used in screen printing. In some examples, the boiling point of the liquid vehicle may be 150° C. or greater at one atmosphere. In some examples the boiling point may be 180 to 200° C. or 150 to 250° C.; other boiling point ranges are also envisaged.

Some fabric-based conductors comprise conductive traces printed on a thick film transfer, which is then adhered to ordinary, nonconductive fabric. One disadvantage of this approach is that the film transfer is typically less flexible than the woven fabric to which it is applied. The potential for detachment of the transfer on repeated stretching, bending, or flexion of the conductor is also an issue. In user-wearable or otherwise flexible electronic component 10, by contrast, the fabric substrate 12 and the electrically conductive pattern 16 are configured to flex and bend through a very large number of cycles without breakage of the conductive traces or separation of the traces from the fabric substrate. This is due to the fact that the traces themselves are highly flexible and bendable due to their elastomeric composition, and that the electronic component as a whole inherits the full flexibility and bendability of the fabric substrate (as no transfer layer is required).

In principle, various printing technologies may be used to apply an electrically conductive ink to fabric substrate 12. Due, however, to its speed, scalability and technological simplicity, screen printing is an especially attractive method. Moreover, screen printing can be used for patterns that cannot be deposited in a single stenciling step. However, screen printing an electrically conductive ink poses difficulties not encountered in the screen printing of ordinary inks (e.g., for decorative purposes). For instance, extremely small fractures in electrically conductive pattern 16 that may occur on flexion of electronic component 10 may cause a loss of electrical conduction through pattern 16. Moreover, conductive-ink formulations typically contain relatively large densities of rigid, electrically conductive particles, to ensure adequate conductance of the residue. The high densities of rigid particles may exacerbate the tendency of the pattern to fracture upon flexion. Accordingly, a series of approaches are disclosed herein to address the above issues and thereby enable practical, low-cost screen printing of an electrically conductive ink on a flexible fabric substrate.

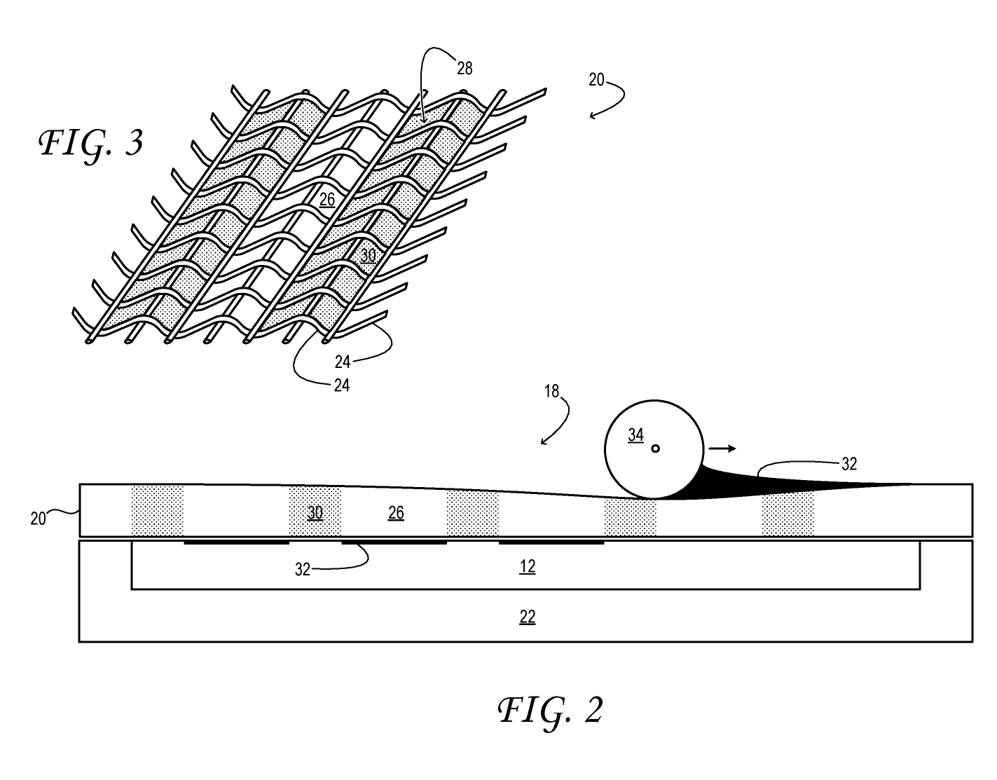

FIG. 2 shows aspects of an example screen printing rig 18 with fabric substrate 12 positioned thereon. The screen printing rig includes a screen 20 configured for screen printing an electrically conductive-ink pattern onto the fabric substrate. In FIG. 2, the screen is stretched over a rigid frame 22 to ensure flatness and accurate registration of the pattern on the screen (vide infra) to the underlying fabric substrate.

As shown in FIG. 3, screen 20 comprises an intimate arrangement of fibers 24 defining a plurality of initially unfilled pores 26 wettable by the electrically conductive ink. In the illustrated example, the screen takes the form of a knit or woven mesh. In other examples, the screen may be non-woven or felted. The screen may comprise metal (e.g., stainless steel), nylon, or polyester fibers, for example.

Continuing in FIG. 3, a pore-filling solid may permeate the intimate arrangement of fibers 24 of screen 20 within one or more defined areas 28, thereby defining a pattern of filled pores 30 among the unfilled pores 26. In some examples, the pore-filling solid includes a cured resin.

Returning now to FIG. 2, electrically conductive ink 32 is configured to effectively wet the fibers 24 of screen 20. The wetting force overcomes the surface tension of the ink and allows the ink to pass easily through the unfilled pores. In some examples, the ink viscosity falls within the range of 40 to 120 pascal-seconds, although viscosities outside of this range also may be used. As a result of the relatively low ink viscosity and low surface energy of ink 32 on fibers 24, a conventional roller 34 or squeegee is sufficient to mechanically force the ink through the unfilled pores of the screen and onto fabric substrate 12.

As noted above, electrically conductive ink 32 is formulated for printing electrically conductive pattern 16 on flexible fabric substrate 12. The ink comprises an elastomer. The elastomer may include one or more of a fluoroelastomer, a polyurethane, and a polysiloxane, for example. More particular examples include copolymers of vinylidene fluoride and hexafluoropropylene, terpolymers of vinylidene fluoride, hexafluoropropylene and tetrafluoroethylene, terpolymers of vinylidene fluoride, hexafluoropropylene and perfluoromethylvinylether, Voranate®, Isonate®, and Sylgard® from DOW (Midland, Mich.), Mondur® from Bayer (Leverkusen, Germany), BASF Lupranat® and Elastocoat® from BASF (Ludwigshafen, Germany), Suprasec® from Huntsman (The Woodlands, Tex.), and Wannate® from Yantai Wanhua US (Houston, Tex.).

Mixed with the elastomer of electrically conductive ink 32 is a liquid vehicle capable of swelling the elastomer. The term ‘swelling’ is to be understood as used in the field of modern polymer chemistry. For instance, although the liquid vehicle may not dissolve the elastomer, molecules of the liquid vehicle may associate with the oligo- or macromolecular chains of the elastomer, and to such a degree as to enforce a preferred conformation of the elastomer chains and weaken the attractive forces among the chains. The liquid vehicle may be a chemical solvent with a boiling point of 150° C. or greater at one atmosphere. In some examples, the liquid vehicle may include a ketone or aldehyde. In some examples, the liquid vehicle may include a carboxylic acid. In one, nonlimiting example, the liquid vehicle includes butyl carbitol acetate. In other examples, the liquid vehicle may include pentanoic acid, hexanoic acid, heptanoic acid, octanoic acid, nonanoic acid, and/or decanoic acid. In some, non-limiting examples, a surfactant may be dissolved in the liquid vehicle to improve ink stability and reduce surface tension.

Without wishing to be bound by theory, the benefit of the relatively high boiling point of the liquid vehicle may be explained as follows. For most ink-printing applications a relatively volatile liquid vehicle is chosen in order to speed drying. When printing an electrically conductive ink into a fabric substrate, however, it is undesirable for the ink to start drying until it has fully permeated the fiber structure of the substrate. If the liquid vehicle should begin to dry while the ink is still descending through the fiber structure, the electrically conductive residue will then concentrate at the upper surface, and relatively little residue will penetrate down to the lower surface. The resulting pattern, therefore, may be thin, dense, and susceptible to fracture. By incorporating a liquid vehicle with a boiling point of 150° C. or greater, premature drying is lessened, and the electrically conductive residue is deposited more homogeneously within the fiber structure of the fabric substrate. This provides a more durable pattern, which is less likely to fracture when the electronic component is stretched or bent.

Continuing, electrically conductive ink 32 further comprises a plurality of non-spherical, electrically conductive particles suspended in the liquid vehicle. In some examples, the non-spherical, electrically conductive particles may include particles having a flake-like or plate-like morphology. In other examples, the non-spherical, electrically conductive particles may include particles having a needle-like morphology. In yet other examples, the non-spherical, electrically conductive particles may include nanotubes. Without tying this disclosure to any particular theory, it is believed that electrically conductive particles having large, nonunit aspect ratios may provide advantageous properties to the dried residue of an electrically conductive ink. This is because in the dried residue of the ink, such particles can move apart from each other responsive to bending or stretching of the host matrix, yet remain in intimate contact with each other. By contrast, spherical particles would move out of contact in response to bending or stretching of the matrix along any direction. The elemental composition of the non-spherical, electrically conductive particles is not particularly limited. As examples, the non-spherical, electrically conductive particles may comprise one or more of silver and carbon.

The elastomer, liquid vehicle, and electrically conductive particles of electrically conductive ink 32 may be included in any suitable relative proportions. In some examples, the relative mass of elastomer to liquid vehicle to conductive particles is 4:1:3. In other examples, the relative mass is 3:1:3. In still other examples, the relative mass is 2:1:3. Accordingly, the electrically conductive particles may comprise 30 to 60% by mass of the ink; the elastomer may comprise 10 to 20% by mass of the ink; and the liquid vehicle may comprise 30 to 60% by mass of the ink. It will be noted that relative masses outside of these example ranges are also envisaged.

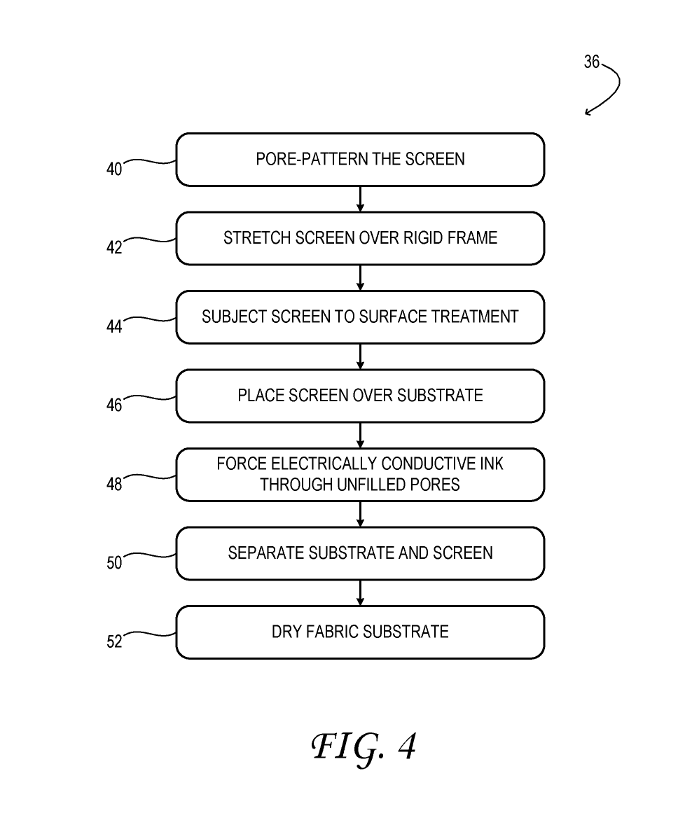

FIG. 4 illustrates an example method 36 of printing an electrically conductive pattern on a flexible fabric substrate. Method 36 comprises, at 40 pore-patterning a printing screen by filling the pores of the screen within a defined area of the screen. This action defines a pattern of filled and unfilled pores, which ultimately will be transferred onto the fabric substrate as an electrically conductive pattern. In some examples, the act of filling the pores may include applying a curable resin to a defined area of the screen and then curing the resin. The type of resin and the curing thereof is not particularly limited. The resin may be thermally cured or photocured (e.g., UV-cured) using a mask bearing the desired pattern, for instance. At 42 of method 36, the screen is stretched over a rigid frame.

At 44 of method 36, the screen is optionally subjected to surface treatment to improve wettability by the electrically conductive ink. The surface treatment may include treatment with one or more of a detergent such as an anionic surfactant, a degreasing base such as ammonia or trisodium phosphate, an oxidant such as hydrogen peroxide or sodium hypochlorite, a surface-oxide dissolving acid such as hydrochloric acid, a solvent such as water or acetone, and/or a drying agent such as steam, compressed air, or nitrogen. At 46 the screen is then placed over the fabric substrate.

At 48 the electrically conductive ink is forced through the unfilled pores of the screen and onto the fabric substrate. The same printing screen may be used repeatedly for numerous screen-print applications of the electrically conductive ink. The electrically conductive ink may be forced through the unfilled pores mechanically, for example by using a conventional roller or squeegee. In other examples, compressed air or a compressed gas may be used along with, or instead of the roller or squeegee. At 50 the fabric substrate and screen are separated to reveal the electrically conductive pattern. At 52 the fabric substrate is dried in order to drive off the liquid vehicle from the electrically conductive link and leave behind an electrically conductive residue in the form of the desired pattern.

In sonic scenarios, the electrically conductive ink, having traversed the pore structure in the unfilled areas of the screen, may further reveal a more detailed indication of the pore structure of the screen. For instance, if the surface energy of the electrically conductive ink on the fabric substrate is low enough to overcome the tendency of the ink droplets to coalesce, then an indication (or shadow) of the pore structure of the screen itself may be revealed in the ink pattern. The indication may reveal, for a regular, periodic mesh of the screen, periodic deposits of ink arranged at the same pitch as the pores of the screen. An indication of the pore structure of the screen may be revealed by close examination of the pattern of electrically conductive residue, in some examples. In other scenarios, the electrically conductive ink, upon reaching the fabric substrate, may coalesce thereon to a greater degree. The coalescence of the electrically conductive ink may leave no sign of the detailed pore structure of the screen, but may smooth out the shadowing effect of the screen.

No aspect of the above drawings or description should be interpreted in a limiting sense, for numerous variations, extensions, and omissions are envisaged as well. For instance, the patterning of electrically conductive ink on a fabric substrate is applicable to numerous uses besides forming traces for flexible electronic components. Examples include the manufacture of flexible, anti-static textiles, RFID textiles, and the like. Furthermore, electrically conductive patterns may be used as electrodes for subsequent electrochemical deposition in correspondingly patterned areas of a fabric substrate. Finally, it is also envisaged that the above methods may be applied to electrically conductive inks that exhibit conductivity even in the liquid/gel state and are encapsulated (rather than dried) to form flexible, electrically conductive traces on various substrates.

Another example provides an ink formulated for printing an electrically conductive trace on a flexible fabric substrate. The ink comprises an elastomer, a liquid vehicle, and a plurality of conductive particles. The liquid vehicle is mixed with the elastomer and capable of swelling the elastomer. The liquid vehicle has a boiling point of 150° C. or greater at one atmosphere. The plurality of non-spherical, electrically conductive particles are suspended in the liquid vehicle.

In some implementations, the elastomer includes a fluoroelastomer. In some implementations, the elastomer includes a polyurethane. In some implementations, the elastomer includes a polysiloxane. In some implementations, the non-spherical, electrically conductive particles include flakes. In some implementations, the non-spherical, electrically conductive particles include needles. In some implementations, the non-spherical, electrically conductive particles include nanotubes. In some implementations, the non-spherical, electrically conductive particles comprise silver. In some implementations, the non-spherical, electrically conductive particles comprise carbon. In some implementations, the liquid vehicle includes a ketone or aldehyde. In some implementations, the liquid vehicle includes a carboxylic acid. In some implementations, the liquid vehicle includes butyl carbitol acetate.

Another example provides a method of printing an electrically conductive trace on a flexible fabric substrate, the method comprising: placing a screen over the fabric substrate, the screen having a plurality of filled pores and a plurality of unfilled pores; forcing an ink through the unfilled pores of the screen and onto the fabric substrate, the ink comprising an elastomer, a liquid vehicle capable of swelling the elastomer and having a boiling point of 150° C. or greater at one atmosphere, and a plurality of non-spherical electrically conducting particles; and separating the fabric substrate and the screen.

In some implementations, the fabric substrate comprises a fabric. In some implementations, the fabric substrate includes spandex and/or tricot. In some implementations, forcing the ink through the unfilled pores includes forcing mechanically. In some implementations, the screen comprises a knit or woven mesh.

Another example provides a fabric having one or more electrically conductive traces arranged therein, the fabric comprising: an arrangement of threads; and contained within the arrangement of threads, non-volatile residue of an ink comprising an elastomer, a liquid vehicle capable of swelling the elastomer and having a boiling point of 150° C. or greater at one atmosphere, and a plurality of non-spherical conducting particles.

In some implementations, the threads include cotton and/or polyester. In some implementations, the non-spherical conducting particles include silver flakes.

It will be understood that the configurations and/or approaches described herein are exemplary in nature, and that these specific implementations or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. An ink formulated for printing an electrically conductive trace on a flexible fabric substrate, the ink comprising:
an elastomer;
a liquid vehicle mixed with the elastomer, the liquid vehicle capable of swelling the elastomer, the liquid vehicle having a boiling point of 150° C. or greater at one atmosphere; and
a plurality of non-spherical, electrically conductive particles suspended in the liquid vehicle.

2. The ink of claim 1 wherein the elastomer includes a fluoroelastomer.

3. The ink of claim 1 wherein the elastomer includes a polyurethane.

4. The ink of claim 1 wherein the elastomer includes a polysiloxane.

5. The ink of claim 1 wherein the non-spherical, electrically conductive particles include flakes.

6. The ink of claim 1 wherein the non-spherical, electrically conductive particles include needles.

7. The ink of claim 1 wherein the non-spherical, electrically conductive particles include nanotubes.

8. The ink of claim 1 wherein the non-spherical, electrically conductive particles comprise silver.

9. The ink of claim 1 wherein the non-spherical, electrically conductive particles comprise carbon.

10. The ink of claim 1 wherein the liquid vehicle includes a ketone or aldehyde.

11. The ink of claim 1 wherein the liquid vehicle includes a carboxylic acid.

12. The ink of claim 1 wherein the liquid vehicle includes butyl carbitol acetate.

13. A method of printing an electrically conductive trace on a flexible fabric substrate, the method comprising:
placing a screen over the fabric substrate, the screen having a plurality of filled pores and a plurality of unfilled pores;
forcing an ink through the unfilled pores of the screen and onto the fabric substrate, the ink comprising an elastomer, a liquid vehicle capable of swelling the elastomer and having a boiling point of 150° C. or greater at one atmosphere, and a plurality of non-spherical electrically conducting particles; and
separating the fabric substrate and the screen.

14. The method of claim 13 wherein the fabric substrate comprises a knit or woven fabric.

15. The method of claim 13 wherein the fabric substrate includes spandex and/or tricot.

16. The method of claim 13 wherein forcing the ink through the unfilled pores includes forcing mechanically.

17. The method of claim 13 wherein the screen comprises a knit or woven mesh.

18. A fabric having one or more electrically conductive traces arranged therein, the fabric comprising:
an arrangement of threads; and
contained within the arrangement of threads, non-volatile residue of an ink comprising an elastomer, a liquid vehicle capable of swelling the elastomer and having a boiling point of 150° C. or greater at one atmosphere, and a plurality of non-spherical conducting particles.

19. The fabric of claim 18 wherein the threads include cotton and/or polyester.

20. The fabric of claim 18, wherein the non-spherical conducting particles include silver flakes.
